(19) United States
(12) Patent Application Publication
(10) Pub. No.: US 2015/0311665 A1
(43) Pub. Date: Oct. 29, 2015

(54) EXTERNAL CAVITY SYSTEM GENERATING BROADLY TUNABLE TERAHERTZ RADIATION IN MID-INFRARED QUANTUM CASCADE LASERS

(71) Applicant: Board of Regents, The University of Texas System, Austin, TX (US)

(72) Inventors: Mikhail Belkin, Austin, TX (US); Karun Vijayraghavan, Austin, TX (US); Yifan Jiang, Austin, TX (US)

(21) Appl. No.: 14/699,301

(22) Filed: Apr. 29, 2015

Related U.S. Application Data
(60) Provisional application No. 61/985,978, filed on Apr. 29, 2014.

(51) Int. Cl. H01S 3/1055; H01S 5/028; H01S 5/34; H01S 5/30

(52) U.S. Cl. CPC H01S 3/1055; H01S 5/3013; H01S 5/0287; H01S 5/3402

(57) ABSTRACT

A broadly tunable terahertz source constructed as an external cavity system using a difference-frequency generation quantum cascade laser source. The external cavity system includes an external diffraction grating configured to tune and reflect mid-infrared emission at a first wavelength. The laser includes a mid-infrared feedback grating defined in the laser waveguide of the laser to fix mid-infrared lasing at a second wavelength. Alternatively, two external diffraction gratings may be configured to tune and reflect mid-infrared emission at a first wavelength and a second wavelength. Tunable terahertz radiation is then generated at frequency ω_{THz}=|ω₁−ω₂|, where ω₁ and ω₂ are the frequencies of the first and second mid-infrared lasing wavelengths.

### CROSS REFERENCE TO RELATED APPLICATIONS

This application is related to the following commonly owned co-pending U.S. patent application:

Provisional Application Ser. No. 61/985,978, “An External Cavity System Generating Broadly Tunable Terahertz Radiation in Mid-Infrared Quantum Cascade Lasers,” filed Apr. 29, 2014, and claims the benefit of its earlier filing date under 35 U.S.C. §119(e).

### GOVERNMENT INTERESTS

This invention was made with government support under Grant Nos. N66001-12-1-4241 awarded by Defense Advanced Research Projects Agency and ECCS-1150449 and ECCS-0925217 awarded by National Science Foundation. The U.S. government has certain rights in the invention.

### TECHNICAL FIELD

The present invention relates generally to terahertz technology, and more particularly to an external cavity system generating broadly tunable terahertz radiation in mid-infrared quantum cascade lasers.

### BACKGROUND

A major impediment towards wide scale commercialization of terahertz (THz) technology is the lack of an economical, compact, widely-tunable, room-temperature operable THz source, particularly in the 1 THz to 6 THz range. Electrically-pumped semiconductor-based sources are attractive because of their operating simplicity and potential for mass production.

A compact, tunable THz system can be used in applications related but not limited to: illicit drug detection, explosives detection, chemical and biological warfare agent detection, chemical spectroscopy, analysis of proteins/DNA, imaging of nonpolar materials (e.g., plastics, paper and ceramics), process control inspection, pharmaceutical quality control, medical imaging and diagnostics, and security screening.

One technique to generate THz radiation is through the use of a quantum cascade laser. A quantum cascade laser (QCL) is a semiconductor laser that emits in the mid- to far-infrared portion of the electromagnetic spectrum. Unlike typical interband semiconductor lasers that emit electromagnetic radiation through the recombination of electron-hole pairs across the material band gap, QCLs are unipolar and laser emission is achieved through the use of intersubband transitions in a repeated stack of semiconductor multiple quantum well heterostructures.

THz QCLs are a promising source technology for the 1 THz to 6 THz spectral range; however, they still require cryogenic cooling to operate and their tuning range is limited by the available gain bandwidth. An alternative approach to generate room-temperature THz radiation in QCLs are sources based on intracavity difference-frequency generation (DFG) in dual-wavelength mid-infrared (mid-IR, λ=3-15 μm) QCLs designed to have giant optical nonlinearity in the active region. These sources (referred to as THz DFG-QCLs here) operate at room temperature and are uniquely suited to provide output over a wide range of THz frequencies since the mid-IR frequencies in a QCL can be tuned well over 5 THz and optical nonlinearity for intracavity THz DFG is not expected to change significantly over several THz of tuning.

### BRIEF SUMMARY

The present invention describes a broadly tunable THz difference-frequency generation (DFG) quantum cascade laser (QCL) system in which diffraction gratings external to the laser cavity and diffraction gratings monolithically integrated in the laser cavity are used to select and tune the emission frequencies of mid-IR pumps operating at frequencies ω_{Thz} and ω₂ so as to produce tunable THz emission from the THz DFG-QCL at frequency ω_{THz}=|(ω₁−ω₂|.

In one embodiment of the present invention, a tunable THz source system is comprised of a THz DFG-QCL laser bar, a lens positioned in close proximity to a one facet of the laser, and a diffraction grating positioned on a motion control stage. The components are assembled to form a THz external-cavity system. The lens is configured to collimate mid-infrared emission from the laser onto the diffraction grating. Furthermore, the lens is configured to focus mid-infrared radiation reflected from the diffraction grating back into the active region of the quantum cascade laser source, where the diffraction grating is motion controlled to specifically tune and select one of the mid-IR lasing frequency ω₂. Additionally, the THz DFG-QCL has a mid-infrared feedback grating monolithically defined in one or more of waveguide cladding layers to select mid-infrared lasing a specific frequency ω₁, where terahertz radiation is generated in the active region at frequency ω_{THz}=|ω₁−ω₂|. Additionally, the THz DFG-QCL source is configured for THz DFG inside of the laser material and is comprised of a substrate, and one or more lower cladding waveguide semiconductor layers positioned on top of the substrate. Additionally, positioned on top of the lower cladding layers is an active region arranged as a multiple quantum well structure that provides laser gain for mid-infrared generation and optical nonlinearity for THz DFG. Additionally, the laser comprises one or more upper cladding waveguide semiconductor layers positioned on top of the active region, and one or more contact layers positioned on top of the upper cladding to facilitate current injection into the laser waveguide. The THz DFG-QCL may be configured with a modal phase-matched waveguide scheme as described in the M. A. Belkin et al., “Terahertz quantum-cascade-laser source based on intracavity difference-frequency generation,” Nature Photonics, vol. 1, pp. 288-292 (2007), a Cherenkov phase-matched emission scheme for THz emission as described in Vijayraghavan et al., “Terahertz Sources Based on \check{C}erenkov Difference-Frequency Generation in Quantum Cascade Lasers,” Appl. Phys. Lett., vol. 100, article number 251104 (2012), or any other schemes that generated THz radiation via DFG process inside of the QCL material. Additionally, the THz DFG-QCL may have antireflection coatings for mid-IR and/or THz waves deposited on one or more of the device facets. Additionally, the THz DFG-QCL may have high reflection coatings for mid-IR and/or THz waves deposited on one or more the device facets.

In another embodiment of the present invention, the tunable THz source system comprises a THz DFG-QCL laser bar, a lens positioned in close proximity to one facet of the laser, a beam splitter, and two independently controlled diffraction gratings positioned on a motion control stages. The lens is configured to collimate mid-infrared emission from the laser onto the beam splitter, where the beam splitter directs one portion of the mid-IR radiation to a first diffraction grating, and directs the remainder of said mid-infrared radiation to a second diffraction grating. Furthermore, the lens is configured to focus mid-infrared radiation reflected from the first and second diffraction gratings back into the active region of the quantum cascade laser source, where the first diffraction grating is motion controlled to specifically tune and select mid-IR lasing frequency ω₁, and the second diffraction grating is motion controlled to specifically tune and select mid-IR lasing frequency ω₂. Additionally, the THz DFG-QCL is configured for THz DFG at frequency ω_{THz}=|ω₁−ω₂| in the laser material. The THz DFG-QCL may be configured with a modal phase-matched waveguide scheme as described in the M. A. Belkin et al., “Terahertz quantum-cascade-laser source based on intracavity difference-frequency generation,” Nature Photonics, vol. 1, pp. 288-292 (2007), a Cherenkov phase-matched emission scheme for THz emission as described in Vijayraghavan et al., “Terahertz Sources Based on \check{C}erenkov Difference-Frequency Generation in Quantum Cascade Lasers,” Appl. Phys. Lett., vol. 100, article number 251104 (2012), or any other schemes that generated THz radiation via DFG process inside of the QCL material. Additionally, the THz DFG-QCL may have antireflection coatings for mid-IR and/or THz waves deposited on one or more device facets. Additionally, the THz DFG-QCL may have high reflection coating for mid-IR and/or THz waves deposited on one or more device facets.

The foregoing has outlined rather generally the features and technical advantages of one or more embodiments of the present invention in order that the detailed description of the present invention that follows may be better understood. Additional features and advantages of the present invention will be described hereinafter, which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 is a schematic of the external cavity THz DFG-QCL system with single external cavity grating in accordance with an embodiment of the present invention;

FIG. 2 illustrates a Cherenkov THz DFG-QCL source in accordance with an embodiment of the present invention;

FIG. 3A illustrates the room temperature mid-IR spectra obtained experimentally using the external cavity THz DFG-QCL system with a single external cavity grating in accordance with an embodiment of the present invention;

FIG. 3B illustrates the corresponding room temperature THz spectra obtained experimentally using the external cavity THz DFG-QCL system with a single external cavity grating in accordance with an embodiment of the present invention;

FIG. 4A illustrates the room temperature mid-IR spectra of the present invention for the external cavity THz DFG-QCL system with a mid-IR anti-reflection coating applied to the back laser facet of the THz DFG-QCL source and in which the THz is collected directly through an InP substrate in accordance with an embodiment of the present invention;

FIG. 4B illustrates the corresponding room temperature THz spectra of the present invention for the external cavity THz DFG-QCL system with a mid-IR anti-reflection coating applied to the back laser facet of the THz DFG-QCL source and in which the THz is collected directly through an InP substrate in accordance with an embodiment of the present invention;

FIG. 4C illustrates the corresponding THz far field emission spectra of the present invention for the external cavity THz DFG-QCL system with a mid-IR anti-reflection coating applied to the back laser facet of the THz DFG-QCL source and in which the THz is collected directly through an 350 micron thick InP substrate in accordance with an embodiment of the present invention;

FIG. 5A illustrates the room temperature mid-IR spectra of the present invention for the external cavity THz DFG-QCL system with a mid-IR anti-reflection coating applied to the back laser facet of the THz DFG-QCL source and in which the THz is collected directly through a high-resistivity silicon substrate in accordance with an embodiment of the present invention;

FIG. 5B illustrates the corresponding room temperature THz spectra of the present invention for the external cavity THz DFG-QCL system with a mid-IR anti-reflection coating applied to the back laser facet of the THz DFG-QCL source and in which the THz is collected directly through a high-resistivity silicon substrate in accordance with an embodiment of the present invention;

FIG. 5C illustrates the corresponding THz far field emission spectra of the present invention for the external cavity THz DFG-QCL system with a mid-IR anti-reflection coating applied to the back laser facet of the THz DFG-QCL source and in which the THz is collected directly through an 1000 micron thick high-resistivity silicon substrate in accordance with an embodiment of the present invention; and

FIG. 6 is an alternative embodiment of the present invention of the external cavity THz DFG-QCL system using a dual external grating tuning configuration in accordance with an embodiment of the present invention.

### DETAILED DESCRIPTION

As stated in the Background section, THz QCLs are a promising source technology for the 1-6 THz generation; however, they still require cryogenic cooling to operate. Furthermore, their tuning range is limited by the THz gain bandwidth. An alternative approach to generate widely-tunable THz radiation are sources based on intracavity difference-frequency generation (DFG) in dual-wavelength mid-infrared (mid-IR, λ=3-15 μm) QCLs designed with giant optical nonlinearity in the active region for THz generation. These sources operate at room temperature and are uniquely suited to provide output over a wide range of THz frequencies since the mid-infrared frequencies in a QCL can be tuned well over 5 THz and optical nonlinearity for intra-cavity THz DFG is broadly distributed over several THz of tuning.

The difference in mid-IR pump frequencies ω₁ and ω₂, respectively, determine the THz emission frequency given as ω_{THz}=ω₁−ω₂|. Tunable THz emission is realized by changing frequency (frequencies) of one or both mid-IR pumps with respect to another. The principles of the present invention describe a method of generating broadly tunable THz emission in DFG-QCL sources using an external cavity system for mid-IR wavelength control.

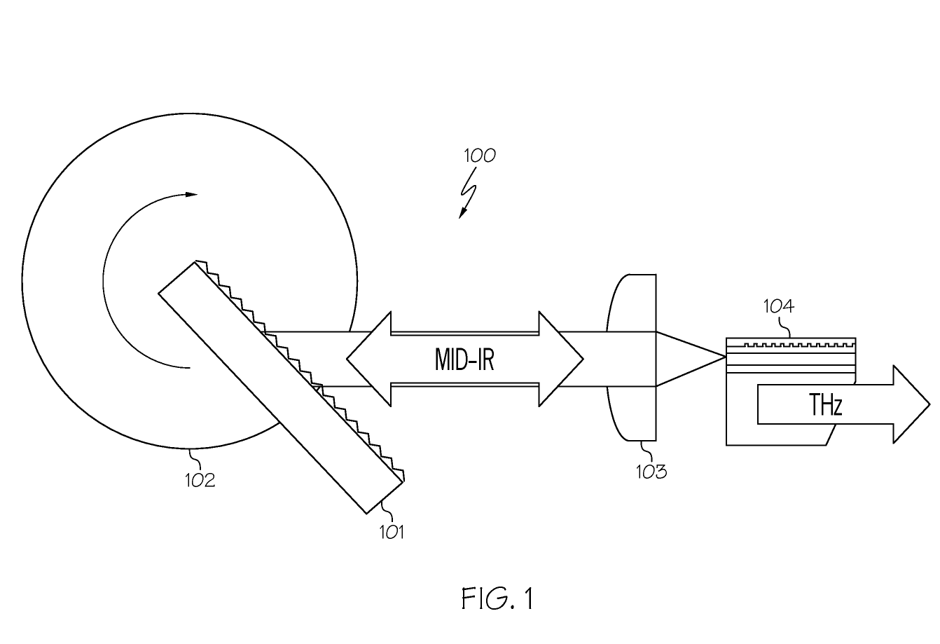

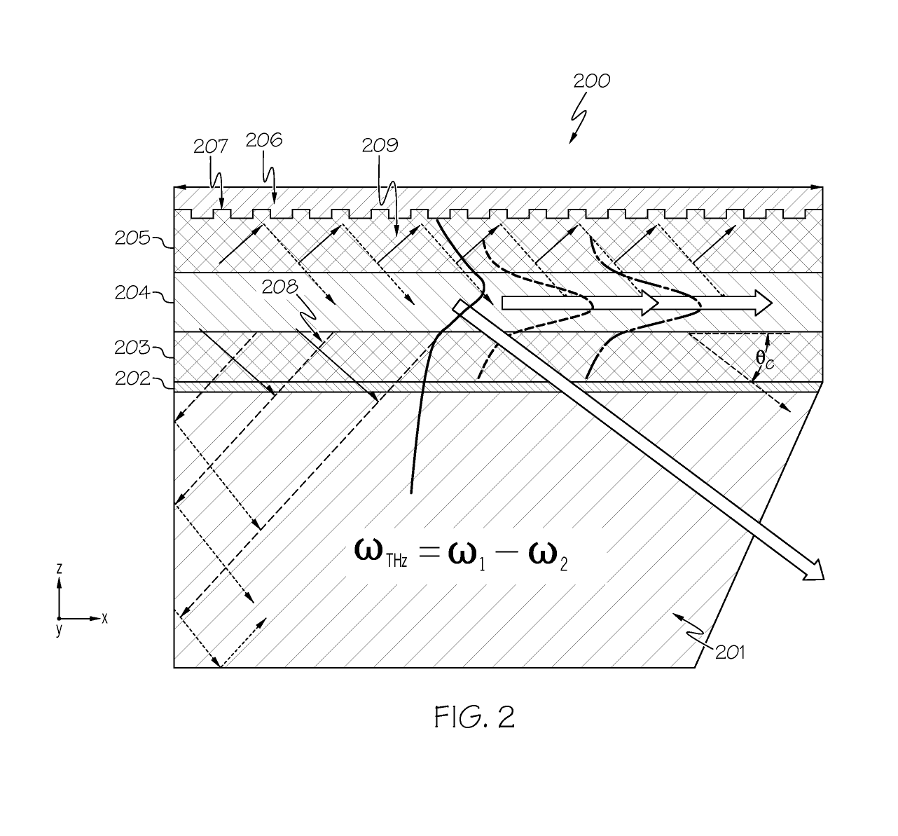

FIG. 1 shows the schematic of the external cavity THz DFG-QCL system 100 in accordance with an embodiment of the present invention. System 100 includes a THz DFG-QCL source 104, an external diffraction grating 101, a motion-control system 102 to manipulate diffraction grating 101, and a lens 103 configured to collimate mid-IR output from the THz DFG-QCL source onto diffraction grating 101 and configured to focus diffracted light from diffraction grating 101 into the DFG source active region (layer 204 of FIG. 2 discussed further below) with integrated optical nonlinearity. Lens 103 can be made of any material transparent in the mid-IR region (e.g., ZnSe or molded Chalcogenide glass) and preferably be anti-reflection coated in the λ=5 μm-12 μm range. The grating is preferably gold coated and blazed for mid-IR wavelengths. In one embodiment, lens 103 is an aspheric anti-reflection collimating lens. In the one embodiment, the THz DFG-QCL source 104 is designed with a Cherenkov emission scheme. In another embodiment, THz DFG-QCL source 104 may be designed for a modal phase matched emission scheme.

A discussion of the THz tuning method in the embodiment of the present invention is now deemed appropriate. THz difference-frequency generation requires simultaneous mid-infrared lasing at two frequencies. A mid-infrared feedback grating monolithically constructed in the waveguide of the Cherenkov THz DFG-QCL source 104 fixes mid-infrared lasing at frequency ω₁. In one embodiment, the feedback grating is constructed as a fixed-period distributed feedback grating (DFB). In another embodiment, the feedback grating is constructed as a distributed Bragg reflector (DBR). The external diffraction grating 101 selects mid-infrared lasing frequency ω₂. The external diffraction grating 101 can be manipulated (e.g., mechanical rotation, translation, etc.) such that it changes lasing frequency ω₂. In this manner, tunable THz radiation is generated at frequency ω_{THz}=|ω₁−ω₂|. A discussion of the THz DFG-QCL source design is now deemed appropriate. To implement a broadly tunable, high-efficiency THz source using DFG-QCL technology, the principles of the present invention use devices designed with a Cherenkov phase-matched emission scheme for broadband THz outcoupling. However, THz DFG-QCLs with modal phase-matching as described in the M. A. Belkin et al., “Terahertz quantum-cascade-laser source based on intracavity difference-frequency generation,” Nature Photonics, vol. 1, pp. 288-292 (2007) or any other THz DFG-QCL sources that generated THz radiation via DFG process inside of the QCL material may also be used in this system. In a Cherenkov emission scheme, the THz radiation is emitted out of the active region at an angle with respect to the propagation direction of the mid-IR pumps as shown in FIG. 2. FIG. 2 illustrates a more detailed schematic of a Cherenkov quantum cascade laser system component 104 in accordance with an embodiment of the present invention. FIG. 2 will be discussed in further detail below. The Cherenkov emission scheme circumvents the problem of high THz absorption and inefficient THz outcoupling to free-space intrinsic to THz DFG-QCLs based on collinear modal phase-matching. The existence of Cherenkov emission in DFG-QCLs was confirmed by Vijayraghavan K. et al., “Terahertz sources based on \check{C}erenkov difference-frequency generation in quantum cascade lasers,” Appl. Phys. Lett., vol. 100, article number 251104 (2012), (hereinafter “Vijayraghavan Reference 1”) using proof-of-principle devices that produced multi-mode THz generation over a 1.2 to 4.5 THz range. However, these sources could not be tuned nor provide single frequency THz emission.

A discussion of the Cherenkov waveguide design is now deemed appropriate in connection with FIG. 2. Cherenkov emission occurs when the phase-velocity of the nonlinear polarization wave in a thin slab of nonlinear optical material is faster than the phase-velocity of the THz radiation in the medium surrounding the slab. In this case, the generated radiation is emitted at the Cherenkov angle θ_{C} from the slab as shown in FIG. 2. In the case of DFG-QCLs, one can write an expression for the nonlinear polarization wave at ω_{THz}=ω₁-ω₂ in the slab waveguide approximation as:

P_{z}⁽²⁾(x,z)=∈₀χ_{zzz}⁽²⁾(z)E_{z}^{ω}^{₁}(z)E_{z}^{ω}^{₂}(z)e^{i(ω}^{_{THz}}^{t-(β}^{₁}^{-β}^{₂}^{)x)} (1)

where the z-direction is normal to the QCL layers and the x-direction is along the waveguide, β₁ and β₂ are the propagation constants for mid-IR pump modes, E_{z}^{ω}^{₁} and E_{z}^{ω}^{₂} (z) are z-components of E-field of the mid-IR pump modes, and χ_{zzz}⁽²⁾(z) is the giant intersubband optical nonlinearity for DFG in the QCL active region. The Cherenkov phase-matching condition is satisfied when

k_{THz} cos θ_{C}=|β₁−β₂| (2)

where k_{Thz} is the wavevector of the Cherenkov wave in the substrate and |β1−β2| is the propagation constant of the nonlinear polarization wave. Since the two mid-IR pump frequencies are close, ω₁≈ω₂, one can write

$$\vert {β}_{1} - {β}_{2} \vert \approx \frac{{n}_{g} {ω}_{THz}}{c} \qquad ( 3 )$$

where

$${n}_{g} = {n}_{eff} ( {ω}_{1} ) + {ω}_{1} \frac{\partial {n}_{eff}}{\partial ω} {\vert}_{ω = {ω}_{1}}$$

is the group effective refractive index at ω₁ and ω_{THz}=ω₁−ω₂. For the devices of the present invention, n_{g} is calculated to be ≈3.372 in the λ=6 μm-12 um range. From equation (2), the Cherenkov angle of emission can be written as:

θ_{C}=cos⁻¹(|β₁−β₂|/k_{THz})=cos⁻¹(n_{g}/n_{sub}) (4)

where n_{sub} is the refractive index of the THz wave in the substrate. In order to produce Cherenkov DFG emission into the substrate, n_{sub} must be larger than n_{g} at ω_{THz}. As demonstrated herein, this condition is satisfied throughout the 1-6 THz spectral range for InP/InGaAs/InAlAs QCLs grown on semi-insulating InP, where the refractive index ranges from 3.5 to 3.8 due to the proximity of the Restrahlenband (III-V LO phonon energies) to THz frequencies. For the devices of the present invention, θ_{C}≈21° for DFG in the whole 1-5 THz range. Since semi-insulating InP is relatively lossless over 1-6 THz, the Cherenkov emission scheme allows for efficient extraction of THz radiation along the whole length of the QCL waveguide. To avoid total internal reflection of the THz Cherenkov wave at the front facet, the substrate has to be polished at a 20°-30° angle as shown in FIG. 2.

In one embodiment, the principles of Cherenkov THz DFG allows one to extract THz radiation along the entire active region layer 204 thereby improving the mid-IR-to-THz conversion efficiency, THz power output, and increasing extending the frequency range of operation, compared to THz DFG-QCLs based on modal phase-matching.

High-performance of the Cherenkov DFG-QCL chips discussed herein resulted in the demonstration, for the first time, an external cavity (EC) DFG-QCL system which is similar in mechanical design and operation to highly-successful widely-tunable mid-IR EC QCL systems. The results were published in Vijayraghavan, K. et al., “Broadly tunable terahertz generation in mid-infrared quantum cascade lasers,” Nature Comm., 4, 2021 (2013) (hereinafter “Vijayraghavan Reference 2”).

It is now deemed appropriate to discuss an example of the device structure of the tunable THz DFG-QCL source 104 (FIG. 1). Referring again to FIG. 2, tunable THz DFG-QCL source 104 includes a quantum cascade laser 200 configured for a Cherenkov emission scheme, which includes a substrate 201 that may be comprised of a III-V semiconductor compound, such as InP. In one embodiment, substrate 201 is formed of semi-insulating or undoped indium phosphide. In one embodiment, substrate 201 has a thickness between 100 μm and 3,000 μm. In another embodiment, substrate 201 has a thickness of less than 100 μm or more than 3,000 μm.

Furthermore, quantum cascade laser 200 includes a doped current extraction semiconductor layer 202 positioned on substrate 201. Furthermore, quantum cascade laser 200 includes an active region layer 204 surrounded by waveguide cladding layers 203, 205. As will be discussed further herein, current extraction layer semiconductor layer 202 is used for lateral current extraction from active region layer 203. In one embodiment, current extraction layer 202 and waveguide clad layer(s) 203 are the same layer. Waveguide clad layers 203, 205 are disposed to form a waveguide structure to guide mid-infrared light by which terahertz radiation generated in active region layer 204 and is emitted by laser 200. Furthermore, quantum cascade laser 200 includes a feedback grating 207, such as a distributed Bragg reflector (DBR) etched into the upper waveguide and determines mid-infrared lasing set by the periodicity of Bragg grating 207. Additionally, metal contact layer(s) 206 (e.g., gold material) on top of the upper side of waveguide clad layer(s) 205 as shown in FIG. 2.

Active region layer 204 includes semiconductor layers that generate light of a predetermined wavelength (for example, light in the mid-infrared wavelength range) and provide giant optical nonlinearity for terahertz difference-frequency generation by making use of intersubband transitions in a quantum well structure. In the present embodiment, in correspondence to the use of an InP substrate 201 as the semiconductor substrate, active region layer 204 is arranged as an InGaAs/InAlAs multiple quantum well structure that uses InGaAs in quantum well layers and uses InAlAs in quantum barrier layers.

Specifically, active region layer 204 is formed by multiple repetitions of a quantum cascade structure in which the light emitting layers and electron injection layers are laminated. The number of quantum cascade structure repetitions in the active region is set suitably and is, for example, approximately 10-80 for mid-infrared QCLs and THz DFG-QCLs.

In one embodiment, active region layer 204 includes one or more different quantum cascade sections designed for a broad mid-IR spectral gain bandwidth spanning anywhere from 0.1 THz-10 THz, and broadly distributed optical nonlinearity for 0.1-10 THz generation

A device structure shown in FIG. 2 represents one possible embodiment of a THz DFG-QCL chip structure used as the system component. Other THz DFG-QCL chips, including devices with modal DFG phase-matching described in U.S. Pat. No. 7,974,325 and in M. A. Belkin et al. “Terahertz quantum-cascade-laser source based on intracavity difference-frequency generation,” Nature Photonics, vol. 1, pp. 288-292 (2007) may also be used in the external cavity system claimed in this patent application.

A discussion of the broad tuning with an external cavity system is now deemed appropriate. Since mid-infrared frequencies in a QCL can be tuned well over 5 THz and optical nonlinearity for intracavity THz DFG is not expected to change significantly over several THz of tuning, DFG-QCLs are uniquely suited to be operated as broadly-tunable THz sources for applications, such as spectroscopy, microscopy, and drug or explosives detection.

In the present embodiment, a 1.7 mm-long 22 μm-wide ridge waveguide Cherenkov DFG-QCL device 200 (i.e., laser 200 of FIG. 2) was mounted in the EC system and contained a mid-infrared feedback grating 207 over nearly the entire length of its waveguide. In the present embodiment, the mid-infrared feedback grating is constructed as distributed feedback grating (DFB). In another embodiment, the feedback grating may be constructed as a distributed Bragg reflector (DBR). In one embodiment, DFB grating 207 has a constant periodicity to provide mid-infrared feedback at mid-IR wavelength of λ₁=10.30 μm.

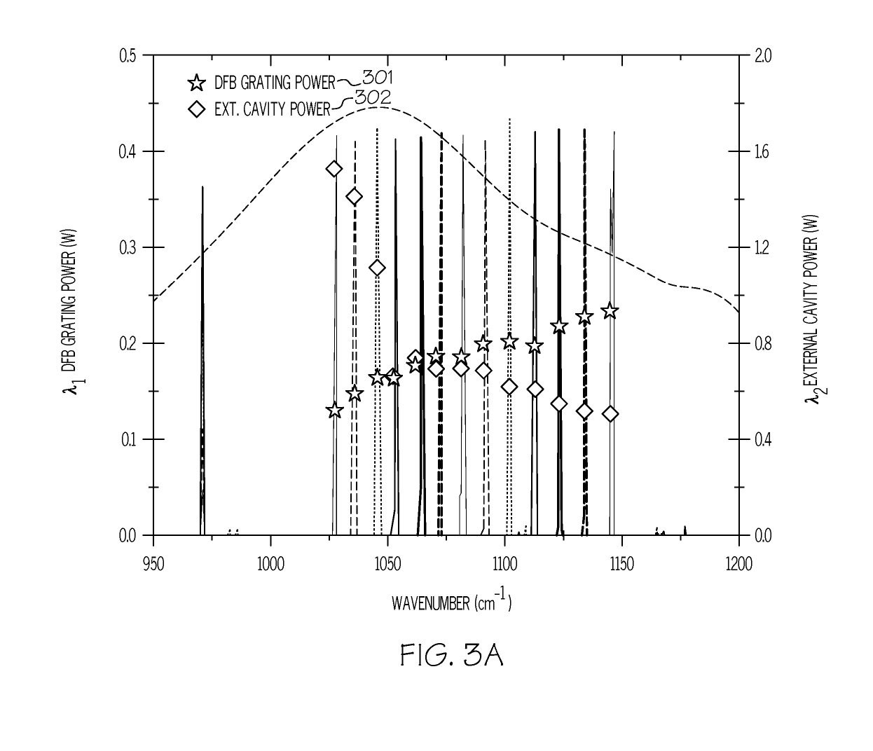

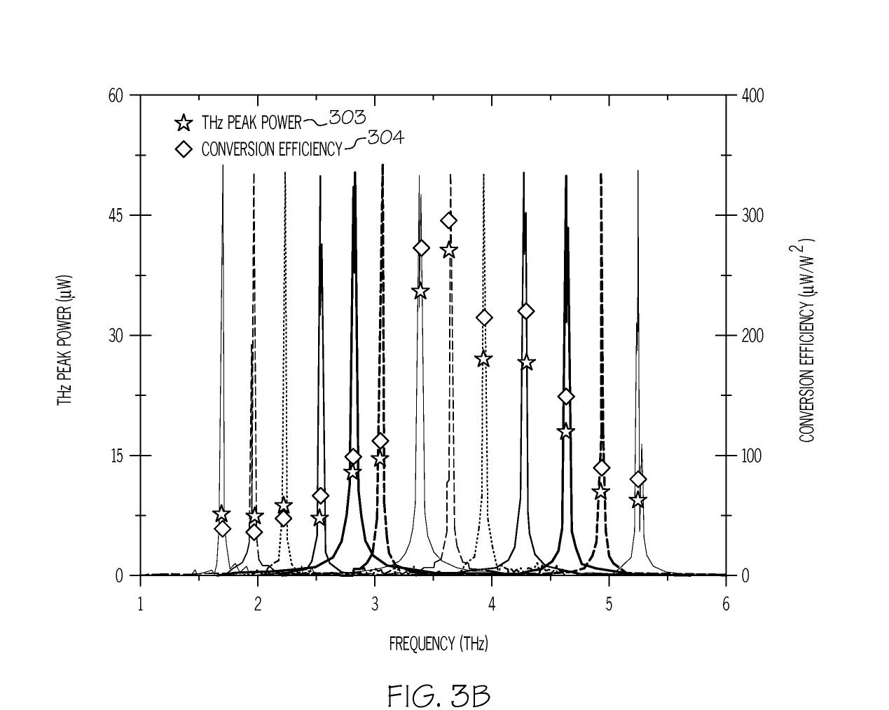

In one embodiment, device 200 includes a DFB grating 207. In the scenario where device 200 includes a single period DFB grating 207, the grating period was kept constant to provide feedback at the mid-IR wavelength of λ₁=10.30 μm. The laser facets were left uncoated for this proof-of-concept demonstration. All measurements were done at room temperature, in a N₂ purged environment, and at a device bias of 8 kA/cm². Spectral measurements were taken with a 0.2 cm⁻¹ resolution. The external cavity was then used to tune the lasing wavelength of the second mid-IR pump from λ₂=8.6 gm to 9.8 μm. The mid-IR spectra, power of an external cavity pump 301 and power of a DFB pump 302 are shown in FIG. 3A in accordance with an embodiment of the present invention. The corresponding THz spectrum, power 303 and conversion efficiency 304 are shown in FIG. 3B in accordance with an embodiment of the present invention. A tuning bandwidth of 3.55 THz for the proof-of-concept external cavity system in accordance with an embodiment of the present invention was demonstrated. Single-frequency emission with a side-mode suppression ratio of better than 15 dB is observed for nearly all THz signals with the exception for the THz emission at the periphery of the systems tuning range that have parasitic lasing peaks in the mid-IR spectrum corresponding to the active region gain peak. At 3.6 THz, a maximum power and conversion efficiency of 40 μW and 0.300 mW/W², respectively, was measured.

Referring back to FIG. 1, the tuning range and mode-hop free tuning performance of EC THz DFG-QCL system 100 can be optimized by depositing a dielectric mid-IR anti-reflection (AR) coating on the DFG-QCL 104 facet that is positioned closest to external grating 101. Proof-of-principle tuning results of the AR coated EC THz DFG-QCL system in the embodiment of the present invention will be discussed.

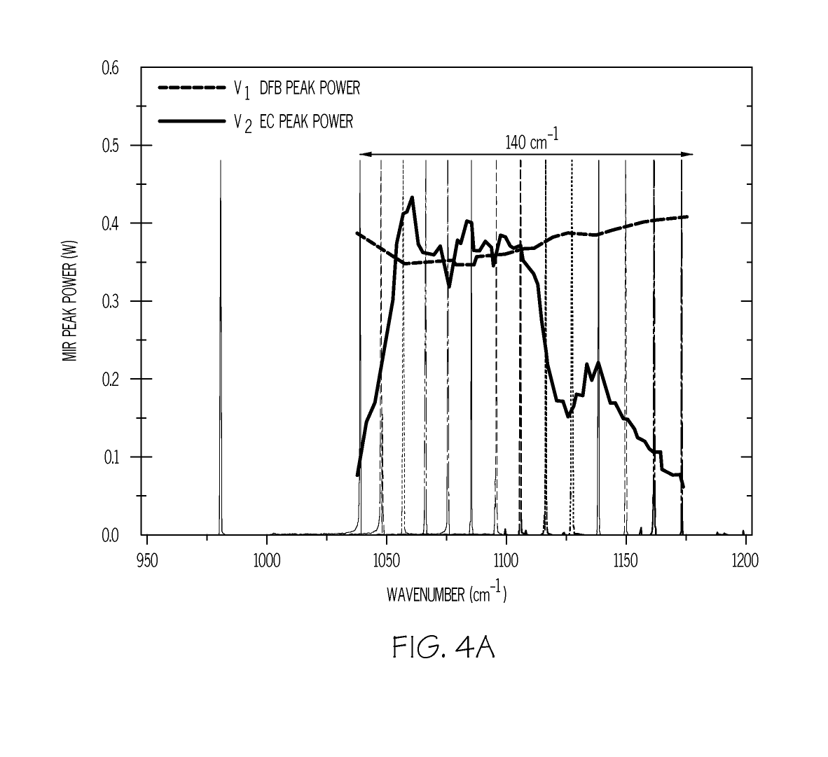

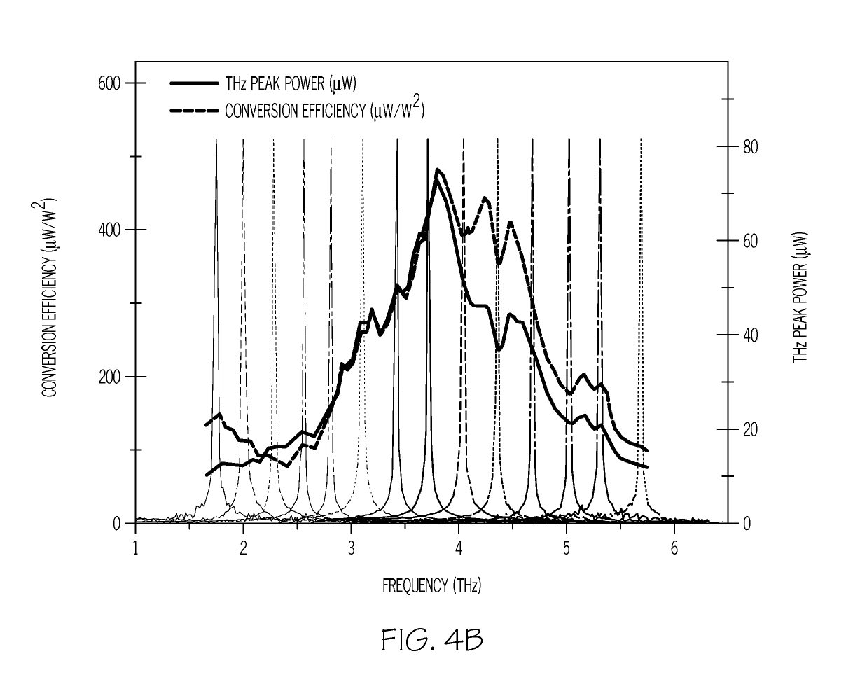

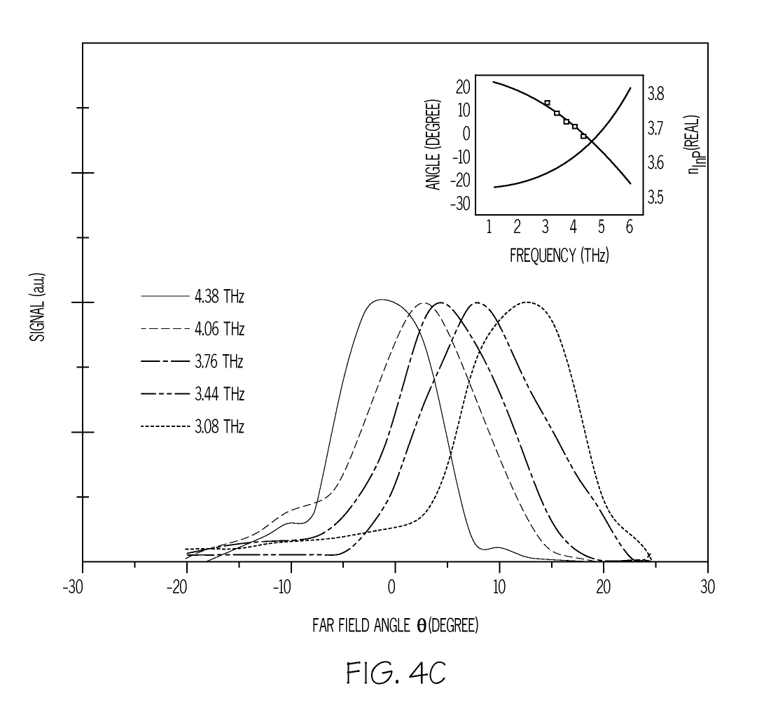

The THz tuning performance of the external cavity system 100 with the THz DFG-QCL laser bar with a back-facet mid-IR AR coating will now be discussed. The device is 1.7 mm-long by 22 um-wide, and contains a 1.38 mm-long surface Bragg grating designed for lasing at ν₁=980 cm⁻¹. The DFB coupling strength is around κL˜4. In one embodiment, a two-layer mid-IR AR coating made of a 650 nm-thick layer of YF₃ followed by 360 nm-thick layer of ZnSe was deposited by electron beam evaporation on the back-facet of the laser. In another embodiment, one or more materials with varying thicknesses may be employed for mid-IR anti-reflection coatings. Room temperature mid-IR tuning performance is shown in FIG. 4A in accordance with an embodiment of the present invention. With one pump fixed at ν₁=980 cm⁻¹, the external diffraction grating tunes the EC modes continuously from 1039 cm⁻¹ to 1172 cm⁻¹. The pump peak powers of the DFB and EC modes measured at different diffraction grating positions is shown in FIG. 4A. Filters were used to spectrally separate the mid-IR pumps during power measurements. The corresponding THz tuning spectra, THz power and mid-IR-to-THz conversion efficiency are shown in FIG. 4B in accordance with an embodiment of the present invention. Measurements were done in a N₂ ambient to reduce loss from water absorption. Tuning from 1.77 THz to 5.7 THz was observed and a maximum THz peak power of 75 μW with a mid-IR-to-THz conversion efficiency of 0.5 mW/W² was observed at 3.8 THz. The tuning bandwidth is 0.38 THz larger compared to systems without AR-coated DFG-QCL chips. Furthermore, mode hoping during tuning was less than 0.3 cm⁻¹, significantly smaller compared to systems without AR-coated DFG-QCL chips presented in Vijayraghavan Reference 2.

Far field emission measurements were carried out and distinct angles of emission at different THz frequencies was observed as shown in FIG. 4C in accordance with an embodiment of the present invention. This “beam steering” effect is due to the refractive index dispersion at THz frequencies in the InP substrate and can be understood by noting that the Cherenkov angle of emission given in Equation 4 is directly dependent on the substrate refractive index at THz frequencies. For the devices of the present invention, constant n_{g} is calculated to be ≈3.372 in the λ=6 μm-12 um range. However, the refractive index of the THz mode in the InP substrate changes from n_{THz}=3.5 at 1 THz to n_{THz}=3.8 at 6 THz, and this large variation results in a 10 degree shift in the Cherenkov emission angle from the nonlinear slab into the substrate. A constant far-field angle of emission at different THz frequencies is preferred for commercial applications because of reduced complexity in system design.

Referring to FIG. 2, to mitigate the far field dispersion, InP substrate 201 can be replaced with a substrate that has very little dispersion at THz frequencies. In one embodiment, high-resistivity silicon substrate (HR-Si) can be employed because there is virtually little refractive index dispersion at THz frequencies in HR-Si.

A discussion regarding the dispersionless broadly tunable EC system with THz DFG-QCL sources bonded to a silicon substrate is now discussed. High-resistivity silicon was used to replace the semi-insulating InP substrate (e.g., substrate 201). The device used in this demonstration was 1.7 mm-long by 22 um-wide, and contained a 1.50 mm-long surface Bragg grating designed for lasing at ν₁=980 cm⁻¹. The InP substrate was lapped down to a thickness of 120 μm. The device was then affixed to a 1 mm thick, 2.8 mm long high-resistivity silicon substrate using 0.5 μm thick SU-8 adhesion layer. To complete the bond, the device was cured at 65° C. and then 95° C. for 30 minutes each, respectively, all the while under a constant pressure. The silicon substrate was polished at a 10° angle to outcouple the THz radiation.

The Cherenkov angles in the InP substrate and Si substrate satisfy the following condition:

n_{g}=n_{THz}^{InP} cos θ_{c}^{InP}=n_{THz}^{Si} cos θ_{c}^{Si} (5)

where n_{THz}^{Inp}, θ_{c}^{InP}, n_{Thz}^{Si}, θ_{c}^{Si} are the refractive index and Cherenkov angle for the InP and Si substrate, respectively. A relatively constant n_{g} and negligible refractive index dispersion of the Si substrate lead to a constant THz beam direction in the 1-6 THz range.

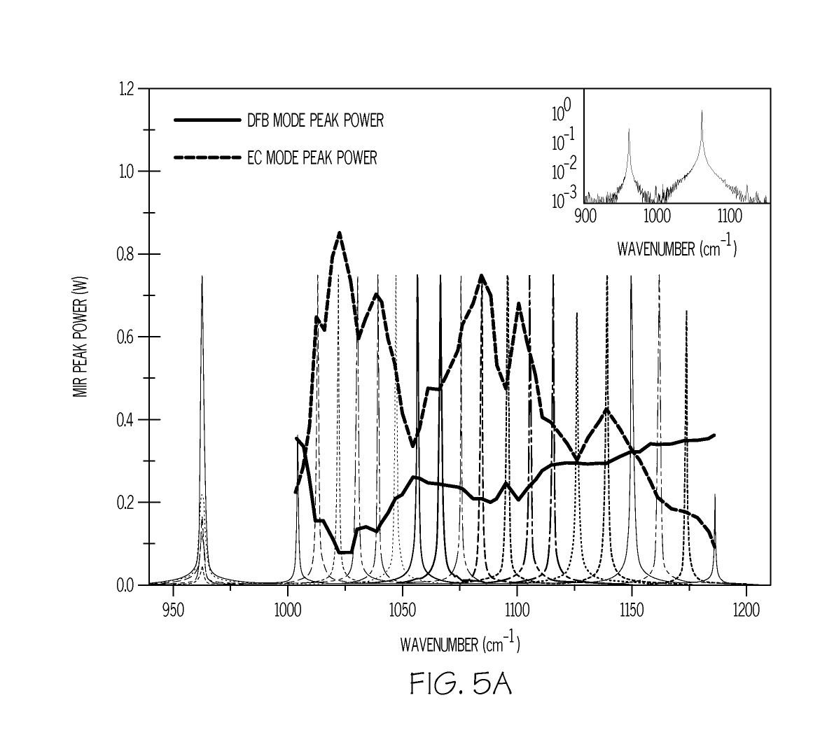

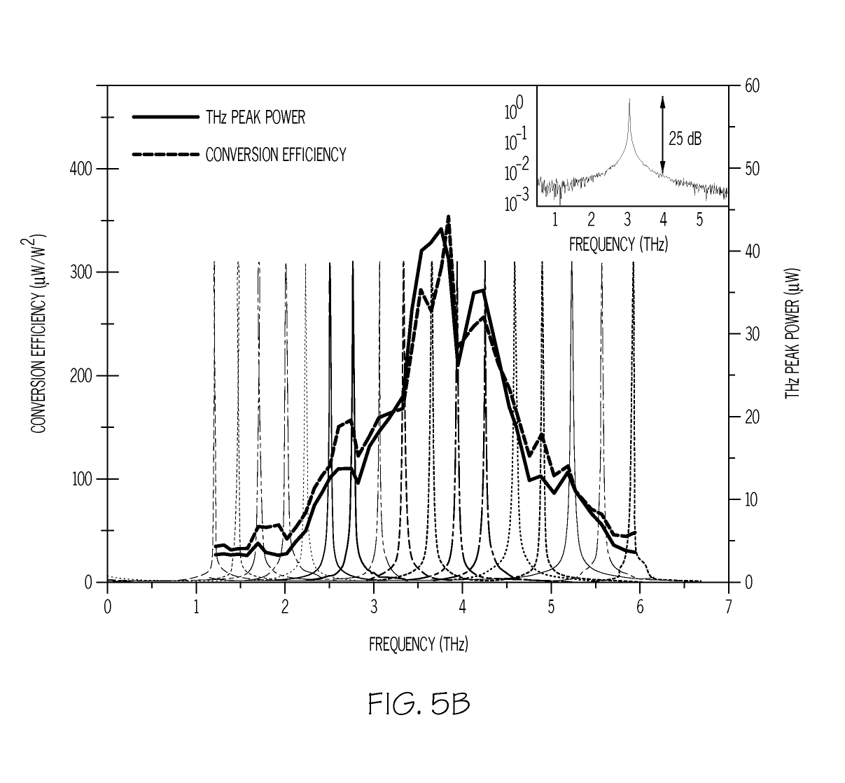

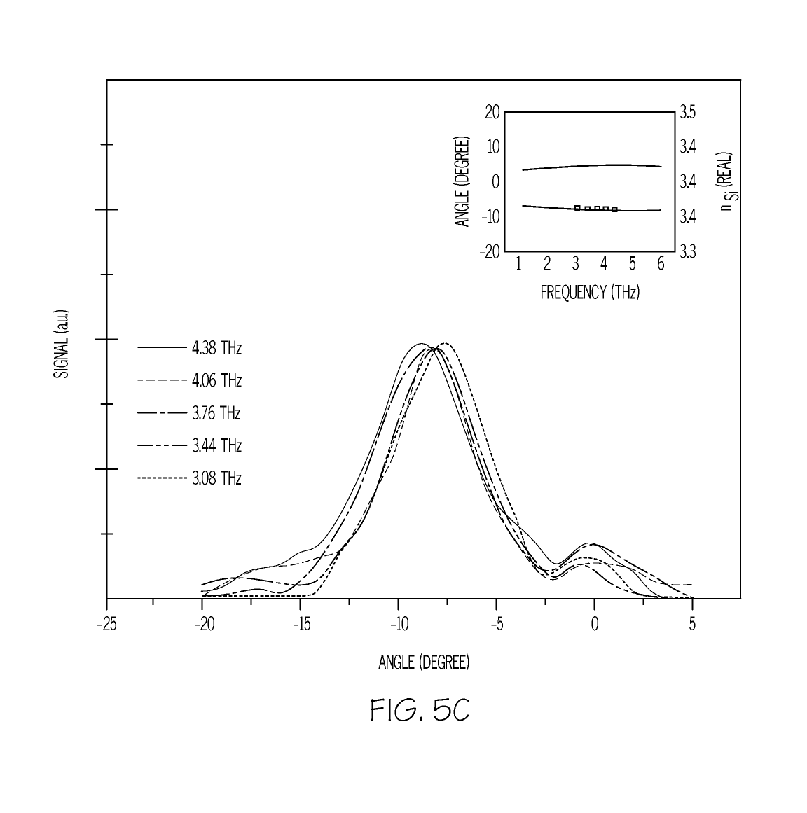

A discussion regarding the performance of a device with Cherenkov radiation through a Si substrate is now deemed appropriate. FIG. 5A displays the mid-IR performance of the dispersionless EC THz DFG-QCL system in accordance with an embodiment of the present invention. Lasing was fixed at ν₁=963 cm⁻¹ by the DFB grating and the external cavity tuned mid-IR pump ν₂ from ν₂=1004 cm⁻¹ to 1185 cm¹. The THz performance is highlighted in FIG. 5B in accordance with an embodiment of the present invention. The peak THz power was 45 μW and the mid-IR to THz conversion efficiency was 0.35 mW/W² at 3.8 THz. The system could be tuned from 1.2 THz to 5.9 THz and had a peak power and mid-IR-to-THz conversion efficiency of 45 μW and 0.35 mW/W2, respectively. A record tuning bandwidth of 4.7 THz is accomplished with the dispersionless EC THz DFG QCL system. Based on mid-IR performance, the corresponding THz tuning should range from 1.2 THz to 6.6 THz, however, absorption loss from the remaining 120 μm-thick InP substrate and Restrahlenband prevented observing emission above 5.9 THz.

Far field emission measurements were carried out in a similar manner mentioned previously. FIG. 5C illustrates the far field profile of the THz emission from a Si substrate in accordance with an embodiment of the present invention. The “beam steering” effect is noticeably absent and a near constant angle of emission is observed from 3.08 THz to 4.38 THz. The result is in good agreement with the theoretical analysis that predicts only 1.2° change in far field angle the 1-6 THz frequency range.

The bonded device of the present invention has a 120 μm-thick InP substrate and the THz emission stills experiences significant loss propagating through this layer. In another embodiment, the InP substrate may be thinner or thicker than 120 μm or it can be removed completely and the QCL structure is affixed directly to another substrate, such as high-resistivity silicon.

The principles of the present invention are not to be limited in scope to the elements depicted in FIG. 1 to enable broadband tuning of THz radiation using mid-infrared quantum cascade lasers. For example, in alternative embodiments, an array for single-frequency monolithic tunable THz sources spanning the 1-6 THz could be used for broad spectral coverage opposed to the setup depicted in FIG. 1.

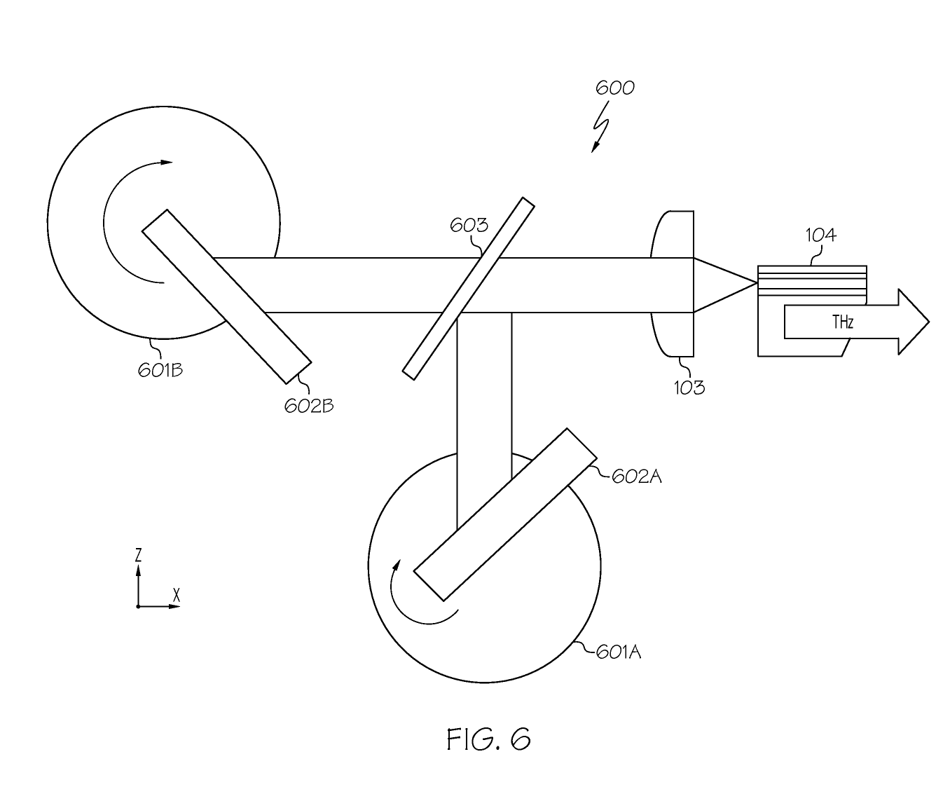

In another embodiment, external cavity THz DFG-QCL system 600 includes two separate rotation and translational stages 601A-601B configured to manipulate external diffraction gratings 602A-602B, respectively, as opposed to having an integrated feedback grating (207 of FIG. 2) and a single external grating, where external diffraction gratings 602A-602B with a beam splitter 603 could be used so that each mid-infrared wave can be independently tuned and focused back into a Fabry-Perot Cherenkov DFG-QCL source 104 as shown in FIG. 6 in accordance with an embodiment of the present invention. In particular, beam splitter 603 is configured to split a beam of light into two beams of light directed to diffraction gratings 602A-602B. Diffraction gratings 602A-602B are configured to diffract an incident light towards lens 103, which is configured to converge the diffracted light into active region layer 204 with optical nonlinearity of laser 200 as discussed above.

Referring again to FIG. 2, alternative outcoupling schemes could be implemented for high performance tuning. In one embodiment, THz radiation is extracted along the entire active region layer 204 thereby improving the mid-IR-to-THz conversion efficiency and THz power output, and outcoupled through the device substrate.

In an alternative embodiment, THz radiation can be extracted along a length of the waveguide structure with substrate 201 being doped and replacing metal layer 206 with a suitable material, such as silicon or germanium, thereby having Cherenkov waves 208, 209 exiting through the top of the device as opposed to the bottom as shown in FIG. 2. In using such an embodiment, a benefit may be to allow laser 200 to operate in a continuous wave operation mode as opposed to using current pulses. Furthermore, as a result of using such an embodiment, smaller emission spectral linewidths may be generated, which may be particularly useful for high precision spectroscopy.

In a further alternative embodiment, substrate 201 is doped and the THz Cherenkov emission 208, 209 is collected laterally along the axis (side) of the waveguide structure of laser 200 (e.g., y-axis of FIG. 2) and outcoupled through a suitable material, such as indium phosphide, silicon or germanium. In using such an embodiment, a benefit may be to allow laser 200 to operate in a continuous wave operation mode as opposed to using current pulses. Furthermore, as a result of using such an embodiment, smaller emission spectral linewidths may be generated, which may be particularly useful for high precision spectroscopy.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A tunable terahertz radiation source configured as an external cavity system, comprising:
a difference-frequency generation quantum cascade laser source designed with integrated laser gain and optical nonlinearity for mid-infrared and terahertz generation, respectively;
a diffraction grating configured to feedback mid-infrared radiation into a laser cavity at one mid-infrared emission frequency (ω₁);
a motion control system to control the diffraction grating so as to provide tuning of the mid-infrared emission frequency ω₁ of the difference-frequency generation quantum cascade laser source; and
a lens configured to collimate mid-infrared radiation from the laser source onto the diffraction grating as well as focus the mid-infrared radiation reflected from the diffraction grating into an active region of the laser source.

2. The external cavity system as recited in claim 1, wherein the lens is an aspheric anti-reflection coating collimating lens in the mid-infrared.

3. The external cavity system as recited in claim 1, wherein the lens is mounted on the motion control system.

4. The external cavity system as recited in claim 1, wherein motion of the diffraction grating is controlled with one or more combinations of translation stage, rotation stage, or microelectromechanical systems.

5. The external cavity system as recited in claim 1, where the difference-frequency generation quantum cascade laser source is configured for Cherenkov THz emission.

6. The external cavity system as recited in claim 1, where the difference-frequency generation quantum cascade laser source is configured for modal phase-matched terahertz emission.

7. The external cavity system as recited in claim 1, wherein the difference-frequency generation quantum cascade laser source has a distributed feedback (DFB) grating defined in a waveguide structure to fix lasing of a second mid-infrared pump frequency (ω₂) at a design mid-infrared frequency.

8. The external cavity system as recited in claim 1, wherein the difference-frequency generation quantum cascade laser source has a distributed Bragg reflector (DBR) defined in a waveguide structure to fix lasing of a second mid-infrared pump frequency (ω₂) at a design mid-infrared frequency.

9. The external cavity system as recited in claim 1, wherein a dielectric mid-infrared anti-reflection coating is deposited on a back laser facet of the difference-frequency generation quantum cascade laser source.

10. The external cavity system as recited in claim 1, wherein a terahertz anti-reflection coating is deposited on a terahertz outcoupling facet of the difference-frequency generation quantum cascade laser source.

11. The external cavity system as recited in claim 1, wherein a high reflectivity coating is applied to facets of the difference-frequency generation quantum cascade laser source.

12. The external cavity system as recited in claim 1, wherein a substrate of the difference-frequency generation quantum cascade laser source comprises an indium phosphide substrate bonded to a silicon substrate.

13. The external cavity system as recited in claim 12, wherein the indium phosphide substrate has a thickness of approximately 100 μm, wherein the silicon substrate has a thickness of approximately 1 millimeter.

14. The external cavity system as recited in claim 12, wherein THz radiation is outcoupled through the silicon substrate.

15. The external cavity system as recited in claim 1, wherein a substrate of the difference-frequency generation quantum cascade laser source is doped.

16. The external cavity system as recited in claim 15, wherein terahertz radiation is collected laterally along an axis of a waveguide structure of the difference frequency generation quantum cascade laser source.

17. The external cavity system as recited in claim 16, wherein the terahertz radiation is outcoupled through indium phosphide, silicon or germanium.

18. The external cavity system as recited in claim 15, wherein terahertz radiation is extracted through a top waveguide of the difference frequency generation quantum cascade laser source.

19. The external cavity system as recited in claim 18, wherein the terahertz radiation is outcoupled through indium phosphide, silicon or germanium.

20. An external cavity system, comprising:
a difference-frequency generation quantum cascade laser source designed with integrated laser gain and optical nonlinearity for mid-infrared lasing and terahertz generation, respectively;
a beam splitter configured to split mid-infrared laser emission into two beams of light directed to a first and a second diffraction grating, wherein the first diffraction grating is configured to tune and reflect mid-infrared emission at a first wavelength, wherein the second diffraction grating is configured to tune and reflect mid-infrared emission at a second wavelength; and
a lens configured to collimate mid-infrared radiation from the laser source onto the beam splitter as well as focus the mid-infrared radiation reflected from the first and second diffraction gratings into an active region of the laser source whereby a tunable THz DFG takes place in the active region at a frequency determined by the first and second diffraction gratings.
